(19) United States
(12) Patent Application Publication
(10) Pub. No.: US 2010/0016029 A1
(43) Pub. Date: Jan. 21, 2010

(54) BACKLIGHT FOR MOBILE PHONE AND METHOD OF MANUFACTURING THE SAME

(75) Inventors: Zhan Lai, Shenzhen (CN); Peng YAO, Shenzhen (CN); Lei ZHONG, Shenzhen (CN); Jiaxin ZHANG, Shenzhen (CN)

Correspondence Address: ALSTON & BIRD LLP, BANK OF AMERICA PLAZA, 101 SOUTH TRYON STREET, SUITE 4000, CHARLOTTE, NC, 28280-4000, US

(73) Assignee: BYD COMPANY LIMITED, Shenzhen (CN)

(21) Appl. No.: 12/502,912

(22) Filed: Jul. 14, 2009

(30) Foreign Application Priority Data
Jul. 17, 2008 (CN) 200810068562.4

(51) Int. Cl. H04M 1/00; G09F 13/08; C23C 14/34; C23C 14/00; C23C 14/28; B29D 11/00

(52) U.S. Cl. 455/566; 362/97.4; 204/192.26; 427/523; 427/595; 264/1.7

(57) ABSTRACT

A mobile phone comprises an outer shell having patterns thereon, a sub-screen and a backlight unit disposed between the outer shell and the sub-screen to illuminate the patterns on the outer shell and display images on the sub-screen. The backlight unit includes a light source to emit light, a light guide disposed underneath the outer shell to direct light emitted from the light source and an optical film formed between the light guide and the sub-screen. The light source is disposed on one end of a stack including the light guide and the optical film. The optical film has a reflection rate and a transmission rate.

### CROSS-REFERENCE TO RELATED APPLICATION

This application claims foreign priority benefits under 35 U.S.C. §119 of Chinese Patent Application Serial No. 200810068562.4, filed on Jul. 17, 2008, the disclosure of which is incorporated herein by reference.

### TECHNICAL FIELD

The present invention relates to mobile phones and manufacturing methods thereof, and more particular to mobile phones with a backlight unit and methods for manufacturing the same.

### BACKGROUND

Mobile phones generally include an outer shell, a main screen, a sub-screen and a backlight unit. The outer shell may have patterns printed on it. The main screen displays a variety of information such as the main menu, pictures, or text messages. The sub-screen displays basic information such as date, time or the like. The backlight unit may generally include a light source and a light guide, or plate, to illuminate patterns formed on the outer shell and display images on the screens.

When light is distributed from the light guide to display images on the sub-screen, it is necessary to ensure uniform illumination across the sub-screen and sufficient luminance to produce good contrast. However, if luminance is too high, the visual effect of the patterns on the outer shell may be adversely affected. In addition, circuits or components covered by the outer shell may become visible which is often not desirable.

### BRIEF SUMMARY

According to one exemplary embodiment of the invention, a mobile phone comprises an outer shell having patterns thereon, a sub-screen and a backlight unit disposed between the outer shell and the sub-screen to illuminate the patterns on the outer shell and display images on the sub-screen. The backlight unit includes a light source to emit light, a light guide disposed underneath the outer shell to direct light emitted from the light source and an optical film formed between the light guide and the sub-screen. The light source is disposed on one end of a stack including the light guide and the optical film. The optical film has a reflective rate and a transmission rate.

According to one exemplary embodiment of the invention, a method of manufacturing a backlight unit comprises providing a light guide, forming an optical film underneath the light guide and providing a light source on an end of the light guide and the optical film for illumination. The optical film has a reflection rate and a transmission rate.

### BRIEF DESCRIPTION OF THE DRAWINGS

The foregoing summary, as well as the following detailed description of the invention, will be better understood when read in conjunction with the appended drawings. The embodiments illustrated in the figures of the accompanying drawings herein are by way of example and not by way of limitation. In the drawings:

FIG. 1 illustrates a cross-sectional view of an outer shell, a backlight unit, and a sub-screen of a mobile phone according to one exemplary embodiment of the present invention; and

FIG. 2 illustrates a cross-sectional view of a light guide according to one exemplary embodiment of the present invention.

### DETAILED DESCRIPTION

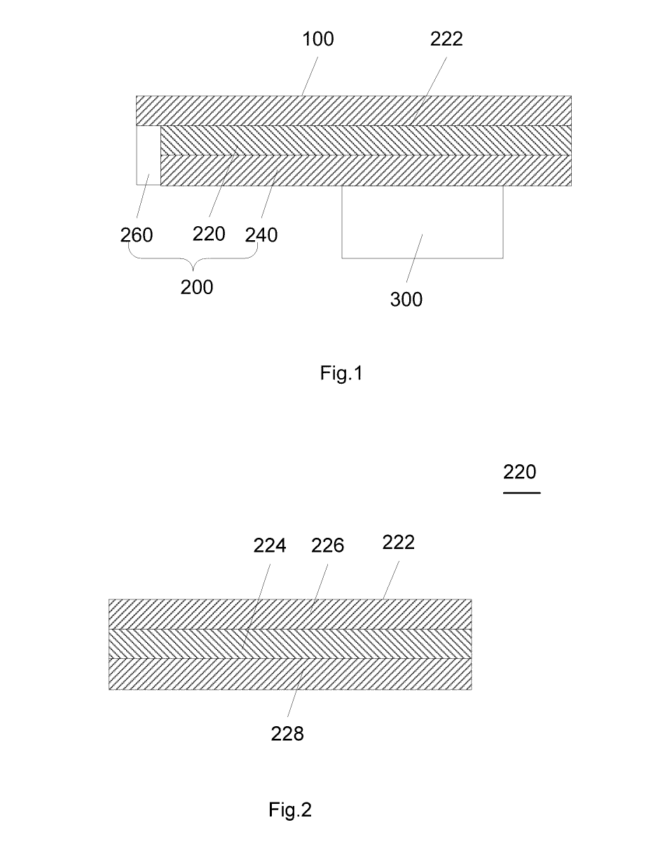

FIG. 1 illustrates an exemplary embodiment of the present invention. As shown in FIG. 1, a mobile phone (not shown) comprises an outer shell 100, a backlight unit 200 and a sub-screen 300. The backlight unit 200, disposed between the outer shell 100 and the sub-screen 300, illuminates patterns printed on the outer shell 100 and displays images on the sub-screen 300. The backlight unit 200 comprises a light source 260 to illuminate the patterns on the outer shell 100 and the sub-screen 300, a light guide 220 to direct light emitted from the light source 260, and an optical film 240 disposed underneath the light guide 220 and above the sub-screen 300. The light guide 220 includes an incident surface 222 from which light is emitted to the outer shell 100. The incident surface 222 is also a reflection and refraction surface which reflects and refracts light to or from the sub-screen 300. The light source 260 may be disposed on one end of a stack comprising the light guide 220 and the optical film 240. The light source 260 may be a single LED or a plurality of LEDs, depending on various applications.

The sub-screen 300 may be a liquid crystal display (LCD) screen or other screens known to one skilled in the art. Optical adhesive may be used for optimal optical bonding. For example, a type of adhesive may be the Optically Clear Adhesive 8171 sold by the 3M Co.

FIG. 2 illustrates a cross-sectional view of the light guide 220 according to one exemplary embodiment. Referring to FIG. 2, the light guide 220 comprises a light guide substrate 224 and a scattering layer 228 formed underneath the light guide substrate 224. When the light source 260 emits light, the light is guided by the light guide 220 and scattered by the scattering layer 228. The scattered light then leaves the incident surface 222 of the light guide 220 to illuminate the outer shell patterns and display images on the sub-screen 300. The light guide substrate 224 may be made of polycarbonate (PC), polymethyl methacrylate (PMMA), silica gel (RUBBER), polyethylene terephthalate (PET) or other materials known to one skilled in the art.

To improve the uniformity and efficiency of luminance, the scattering layer 228 with various scattering patterns may be formed on the opposite side from the incident surface 222 of the light guide substrate 224. The scattering patterns may be provided in dot, ball, ellipsoid, V-shaped groove or other shapes. The scattering patterns may be formed by an injection molding process, a screen printing process, or other processes known to one skilled in the art. When the injection molding process is applied, the scattering patterns may be formed by etching, laser processing or the like. When the screen printing process is applied, the scattering layer 228 may be made of a scattering ink layer and may have a different refractive index than the light guide substrate 224. In various applications, the thickness of the light guide 220 is about 0.1 mm (millimeter) to 1.0 mm. The diameter of the scattering pattern is about 0.03 mm-0.2 mm.

The optical film 240 may exhibit optical properties of reflection and transmission and may serve to increase the brightness of the display and improve display readability. It may also include pretreated transparent or compound material to create different reflection and transmission rate. In one embodiment, the transmission rate of the optical film 240 is about 8% to 30%.

In another embodiment, the optical film 240 may be the Dual Brightness Enhancement Film-Matte (DBEF-M) film sold by 3M Co., the G8010 film provided by Shenzhen Weida Co., or other optical films having similar optical properties known to one skilled in the art. In addition, the optical film 240 may be deposited by physical vapor deposition (PVD) process, ion plating process or other processes known to one skilled in the art to achieve the desired optical properties.

Due to the reflection rate of the optical film 240, when light is emitted and projected to the light guide 220, the light may be mostly reflected by the optical film 240. In this way, components in a vicinity of the sub-screen 300 may not be seen by users thus enhancing the visual effect of images displayed on the sub-screen 300. In addition, the patterns formed on the outer shell 100 are illuminated and shown to users with proper brightness. On the other hand, because the optical film 240 has a transmission rate, the optical film 240 permits partial light to transmit therethrough thus enhancing the brightness of the sub-screen 300, which functions to diminish or eliminate influence between the sub-screen 300 and the backlight unit 200. Moreover, polarized light transmission of the sub-screen 300 may be adjusted along with adjusting the transmission rate of the optical film 240. As a result, desired brightness of the sub-screen 300 may be achieved which may improve display quality and display readability. In this manner, the backlight unit 200 may serve as a light source to illuminate the shell patterns and as a pre-light source to adjust the effect of images displayed on the sub-screen 300. The shell patterns and the images may be concurrently shown to users.

Referring again to FIG. 2, an optional ultraviolet ink layer 226 may be formed on the light guide substrate 224 opposite the scattering layer 228. When light enters the light guide 220, the ultraviolet ink layer 226 serves to scatter incident light. The ultraviolet ink layer 226 may be provided on the upper surface of the light guide 220 by various printing methods such as a silk screen printing, UV pattern process or other printing methods known to one skilled in the art. The solid content of the ink may be greater than 50%. The ink's viscosity (TU #2 cup) may be about 8 to 10 seconds. The thickness of the ultraviolet ink layer 226 may be about 12˜15 μm. The fineness degree of particles may be less than 5 μm. The ink may have a hardness of about 2˜4 H (Japan Mitsubishi pencil hardness). The ink's glossiness may be determined by the sizes of the scattering patterns formed on the reverse side of the light guide 220. When light propagates through the light guide 220, the scattering patterns provided on the scattering layer 228 may be invisible due to the scattering effect of the ultraviolet ink layer 226. When the size of the scattering patterns is small enough, the optional ultraviolet ink layer 226 is not required.

A method of manufacturing the backlight unit 200 described above comprises providing a light guide 220 to direct light, forming an optical film 240 underneath the light guide 220 and providing a light source 260 on one end of the light guide 220 and the optical film 240 for illumination. The optical film 240 may be formed by physical vapor deposition process, ion plating process or other processes known to one skilled in the art. Providing a light guide 220 further comprises providing a light guide substrate 224 and providing a scattering layer 228 underneath the light guide substrate 224. The light guide substrate 224 may be polycarbonate (PC), polymethyl methacrylate (PMMA), silica gel (RUBBER), polyethylene terephthalate (PET) or the like. A plurality of scattering patterns may be formed on the scattering layer 228. The scattering patterns are provided in dot, ball, ellipsoid, V-shaped groove or the like. The scattering patterns are formed by using an injection molding process, a screen printing process or other processes known to one skilled in the art. An optional ultraviolet ink layer 226 may be formed on an upper surface of the light guide substrate 224 opposite the scattering layer 228. The ultraviolet ink layer 226 may be provided on the upper surface of the light guide substrate 224 by various printing methods such as a silk screen printing process, UV pattern process or other processes known to one skilled in the art.

It will be appreciated by those skilled in the art that changes could be made to the examples described above without departing from the broad inventive concept. It is understood, therefore, that this invention is not limited to the particular examples disclosed, but it is intended to cover modifications within the spirit and scope of the present invention as defined by the appended claims.

What is claimed is:

1. A mobile phone, the mobile phone comprising:
an outer shell having patterns thereon;
a sub-screen; and
a backlight unit disposed between the outer shell and the sub-screen to illuminate the patterns on the outer shell and display images on the sub-screen, the backlight unit including
a light source to emit light,
a light guide to direct light emitted from the light source, the light guide being disposed underneath the outer shell, and
an optical film formed between the light guide and the sub-screen, the light source being disposed on one end of a stack including the light guide and the optical film, wherein the optical film having a reflection rate and a transmission rate.

2. The method of claim 1, wherein the optical film is formed by one of physical vapor deposition process and ion plating process.

3. The mobile phone of claim 1, wherein the light guide comprises a light guide substrate and a scattering layer, the scattering layer having a plurality of scattering patterns.

4. The mobile phone of claim 3, wherein the scattering patterns include one of dot, ball, ellipsoid and V-shaped groove shapes.

5. The mobile phone of claim 3, wherein a diameter of the scattering patterns is about 0.03 mm to 0.2 mm.

6. The mobile phone of claim 3, wherein the scattering patterns are formed by using one of an injection molding process and a screen printing process.

7. The mobile phone of claim 1, wherein the light guide further comprises an ultraviolet ink layer, the ultraviolet ink layer scattering incident light.

8. A method of manufacturing a backlight unit, the method comprising:
providing a light guide;
forming an optical film underneath the light guide;
providing a stack including the light guide and the optical film; and
providing a light source on an end of the stack of the light guide and the optical film for illumination, wherein the optical film has a reflection rate and a transmission rate.

9. The method of claim 8, wherein the step of providing an optical film comprises one of physical vapor deposition process and ion plating process.

10. The method of claim 8, wherein a thickness of the light guide is about 0.1 mm to 1.0 mm.

11. The method of claim 8, wherein the step of providing a light guide further comprises providing a light guide substrate and providing a scattering layer underneath the light guide substrate.

12. The method of claim 11 further comprising forming an ultraviolet ink layer on an upper surface of the light guide substrate.

13. The method of claim 12, wherein the ultraviolet ink layer is formed by one of a silk screen printing process and UV pattern process.

14. The method of claim 11, wherein the step of providing a scattering layer further comprises forming a plurality of scattering patterns on the scattering layer, the scattering patterns being provided in one of dot, ball, ellipsoid and V-shaped groove shapes.

15. The method of claim 14, wherein the scattering patterns are formed by using one of an injection molding process and a screen printing process.

16. A backlight, comprising:
a light source to emit light,
a light guide to direct light emitted from the light source, and
an optical film formed on one side of the light guide, the light source being disposed on one end of a stack including the light guide and the optical film, wherein the optical film having a reflection rate and a transmission rate, wherein the light guide comprises a light guide substrate and a scattering layer, the scattering layer having a plurality of scattering patterns.

17. The backlight of claim 16, wherein the optical film is formed by one of physical vapor deposition process and ion plating process.

18. The backlight of claim 16, wherein the scattering patterns include one of dot, ball, ellipsoid and V-shaped groove shapes.

19. The backlight of claim 16, wherein the light guide further comprises an ultraviolet ink layer, the ultraviolet ink layer scattering incident light.

20. The backlight of claim 16, wherein a thickness of the light guide is about 0.1 mm to 1.0 mm.
